(19) United States
(12) Patent Application Publication
(10) Pub. No.: US 2025/0204196 A1
(43) Pub. Date: Jun. 19, 2025

(54) FILTER OPENING ARRANGEMENT STRUCTURE AND DISPLAY PANEL

(71) Applicants: Hefei Visionox Technology Co., Ltd., Hefei (CN); Visionox Technology Inc., Kunshan (CN)

(72) Inventors: Zhiwei ZHOU, Hefei (CN); Jinfang ZHANG, Hefei (CN); Lu ZHANG, Hefei (CN)

(73) Assignees: Hefei Visionox Technology Co., Ltd., Hefei (CN); Visionox Technology Inc., Kunshan (CN)

(21) Appl. No.: 19/066,185

(22) Filed: Feb. 28, 2025

(30) Foreign Application Priority Data
Mar. 4, 2024 (CN) 202410246193.2

(51) Int. Cl. H10K 59/38; H10K 59/121; H10K 59/122; H10K 59/131

(52) U.S. Cl. CPC H10K 59/38; H10K 59/122; H10K 59/131; H10K 59/1213

(57) ABSTRACT

Embodiments of the present application provide a filter opening arrangement structure and a display panel. The filter opening arrangement structure includes: filter openings and light-transmitting holes, where the filter openings include a first filter opening having an extension dimension in a first direction smaller than an extension dimension in a second direction, and the light-transmitting hole is located on a side of the first filter opening with a smaller extension dimension. The light-transmitting hole is located on one side of the first filter opening in the first direction, and the space for providing the light-transmitting hole is relatively large, facilitating an appropriate increase in the size of the light-transmitting hole, to increase the distribution area of the light-transmitting hole. When the filter opening arrangement structure is applied to a display panel, the light transmittance of the display panel can be increased.

### CROSS REFERENCE TO RELATED APPLICATION

The present application claims priority to Chinese Patent Application No. 202410246193.2 filed on Mar. 4, 2024, which is incorporated herein by reference in its entirety. FIELD

The present application relates to the field of display apparatuses, and in particular to a filter opening arrangement structure and a display panel.

### BACKGROUND

Organic light emitting diode (OLED) and flat panel display devices based on technologies such as light emitting diode (LED) have been widely applied to various consumer electronics such as mobile phones, televisions, notebook computers and desktop computers and predominate in display devices thanks to their advantages such as high image quality, energy efficiency, slim design and a wide range of applications.

However, the use performance of conventional OLED display products needs to be improved.

### SUMMARY

Embodiments of the present application provide a filter opening arrangement structure, a display panel and a display device, with the aim of improving the use performance of the display panel.

An embodiment of a first aspect of the present application provides a filter opening arrangement structure, including: a plurality of filter openings and a plurality of light-transmitting holes, where the filter openings includes a first filter opening having an extension dimension in a first direction smaller than an extension dimension in a second direction, the light-transmitting hole is spaced apart from the first filter opening, and the light-transmitting hole is located on a side of the first filter opening with a smaller extension dimension, the first direction intersecting the second direction.

According to any one of the above embodiments of the first aspect of the present application, the first filter opening has an elliptical shape and/or the second filter opening has an elliptical shape.

According to any one of the above embodiments of the first aspect of the present application, there are a plurality of light-transmitting holes, and there are a plurality of light-transmitting holes in the second direction.

According to any one of the above embodiments of the first aspect of the present application, the plurality of light-transmitting holes are disposed equidistantly in the first direction, and the plurality of light-transmitting holes are disposed equidistantly in the second direction.

According to any one of the above embodiments of the first aspect of the present application, a distance between the two first straight edges of the first filter opening is equal to a distance between the two second straight edges of the second filter opening.

According to any one of the above embodiments of the first aspect of the present application, the light-transmitting hole has a polygonal shape.

According to any one of the above embodiments of the first aspect of the present application, an edge of the light-transmitting hole that faces the second filter opening is parallel to the second straight edge, and/or an edge of the light-transmitting hole that faces the first filter opening is parallel to the first straight edge.

According to any one of the above embodiments of the first aspect of the present application, the third filter opening is a green filter opening.

According to any one of the above embodiments of the first aspect of the present application, the third filter opening has an elliptical or circular shape.

According to any one of the above embodiments of the first aspect of the present application, the filter opening includes a first filter opening and a second filter opening, the first filter opening and the second filter opening being disposed on two sides of the same light-transmitting hole, and a minimum spacing between the first filter opening and the light-transmitting hole being in a range from 5 μm to 8 μm;
and/or a minimum spacing between the second filter opening and the light-transmitting hole being in a range from 5 μm to 8 μm.

An embodiment of a second aspect of the present application further provides a display panel, including: a substrate; and a filter layer disposed on one side of the substrate, where the light filter layer includes a plurality of filter openings and a plurality of light-transmitting holes, the filter openings and the light-transmitting holes being arranged according to the filter opening arrangement structure of any one of the above embodiments.

According to any one of the above embodiments of the second aspect of the present application, the display panel further includes a driving device layer including a plurality of first power supply signal lines, an orthographic projection of the first power supply signal line on the substrate being configured to extend in the second direction, where orthographic projections of the first power supply signal lines on the substrate are disposed side by side in the first direction,
where the orthographic projection of at least one of the first filter openings on the substrate at least partially overlaps with the orthographic projection of one of the first power supply signal lines on the substrate, and the orthographic projection of the first filter opening on the substrate is disposed symmetrically with respect to the orthographic projection of the first power supply signal line on the substrate, and/or the orthographic projection of at least one of the second filter openings on the substrate at least partially overlaps with the orthographic projection of one of the first power supply signal lines on the substrate, and the orthographic projection of the second filter opening on the substrate is disposed symmetrically with respect to the orthographic projection of the first power supply signal line on the substrate.

According to any one of the above embodiments of the second aspect of the present application, the first power supply signal line is a driving power supply voltage signal line.

According to any one of the above embodiments of the second aspect of the present application, a plurality of light-transmitting holes are provided, and each first orthographic projection is located between the orthographic projections of the driving transistors of the two driving units on the substrate.

According to any one of the above embodiments of the second aspect of the present application, the second signal line is a light emission control signal line.

According to any one of the above embodiments of the second aspect of the present application, the first signal line and the second signal line are located in different film layers.

According to any one of the above embodiments of the second aspect of the present application, the first signal line is a scanning signal line and the second signal line is a light emission control signal line.

According to any one of the above embodiments of the second aspect of the present application, the first signal line includes a first extension portion and a first bent portion connected to each other, an orthographic projection of the first bent portion on the substrate being located on one side of the first orthographic projection, and the orthographic projection of the first bent portion on the substrate being configured to protrude in a direction away from the first orthographic projection.

According to any one of the above embodiments of the second aspect of the present application, the first extension portion and the first bent portion are alternately connected to each other in the first direction.

According to any one of the above embodiments of the second aspect of the present application, the driving device layer further includes a third signal line, where an orthographic projection of the third signal line on the substrate is located on a side, which faces away from the first orthographic projection, of the orthographic projection of the first signal line on the substrate, and the third signal line includes a second extension portion and a second bent portion connected to each other, an orthographic projection of the second bent portion on the substrate being located on a side, which faces away from the first orthographic projection, of the orthographic projection of the first bent portion on the substrate, and the orthographic projection of the second bent portion on the substrate being configured to protrude in the direction away from the first orthographic projection.

According to any one of the above embodiments of the second aspect of the present application, an orthographic projection of the second extension portion on the substrate is disposed parallel to an orthographic projection of the first extension portion on the substrate, and/or the orthographic projection of the first bent portion on the substrate is disposed equidistantly from the orthographic projection of the second bent portion on the substrate.

According to any one of the above embodiments of the second aspect of the present application, the third signal line and the first signal line are located in different film layers.

According to any one of the above embodiments of the second aspect of the present application, the third signal line and the second signal line are located in the same film layer.

An embodiment of a third aspect of the present application further provides a display device, including the display panel of any one of the above embodiments of the second aspect.

The filter opening arrangement structure according to the embodiments of the present application includes a plurality of filter openings and a plurality of light-transmitting holes, the filter opening including a first filter opening which has a smaller extension dimension in a first direction and a larger extension dimension in a second direction, and the space on one side of the first filter opening in the first direction is relatively large. The light-transmitting hole is spaced apart from the first filter opening in the first direction, that is, the light-transmitting hole is located on one side of the first filter opening in the first direction, and the space for providing the light-transmitting hole is relatively large, facilitating an appropriate increase in the size of the light-transmitting hole, to increase the distribution area of the light-transmitting hole. When the filter opening arrangement structure is applied to a display panel, the light transmittance of the display panel can be increased, to improve the use performance of the display panel.

### BRIEF DESCRIPTION OF THE DRAWINGS

Embodiments of the present application will become more apparent upon reading the following detailed description of non-limiting embodiments with reference to the accompanying drawings, in which the same or similar reference signs indicate the same or similar features.

FIG. 1 is a schematic diagram of a filter opening arrangement structure according to an embodiment of the present application;

FIG. 2 is a schematic structural diagram of a display panel according to an embodiment of the present application;

FIG. 3 is a schematic structural diagram of a cross section along line A-A in FIG. 2;

FIG. 4 is a partial schematic structural diagram of a filter opening arrangement structure according to another embodiment of the present application;

FIG. 5 is a schematic diagram of a filter opening arrangement structure according to still another embodiment of the present application;

FIG. 6 is a schematic structural diagram of film layers of a display panel according to an embodiment of the present application;

FIG. 7 is a partial schematic structural diagram of a display panel according to another embodiment of the present application;

FIG. 8 is a schematic structural diagram of a circuit of a driving unit of a display panel according to an embodiment of the present application;

FIG. 9 is a schematic structural diagram of one of the film layers in FIG. 6;

FIG. 10 is a schematic structural diagram of another one of the film layers in FIG. 6;

FIG. 11 is a schematic structural diagram of two of the film layers in FIG. 6;

FIG. 12 is a schematic structural diagram of one of the film layers in FIG. 11;

FIG. 13 is a schematic structural diagram of the other film layer in FIG. 11;

FIG. 14 is a timing diagram of a display panel according to an embodiment of the present application; and

FIG. 15 is a schematic structural diagram of a display device according to an embodiment of the present application.

### LIST OF REFERENCE SIGNS

10. display panel;
100. substrate;
200. driving device layer; 201. first power supply signal line;
. driving unit; T1. driving transistor; T2. data write transistor; T3. threshold compensation transistor; T4. first reset transistor; T5. first light emission control transistor; T6. second light emission control transistor; T7. second reset transistor; T8. bias transistor; 211. semiconductor layer; 211a. source region; 211b. drain region; 211c. channel region;
220. first signal line; 221. first extension portion; 222. first bent portion; 222a. first section; 222b. second section;
230. second signal line;
240. connecting wire; 241. first segment; 242. inclined segment; 242a. first inclined segment; 242b. second inclined segment; 243. second segment; 244. third segment; 245. fourth segment;
250. third signal line; 251. second extension portion; 252. second bent portion;
300. first electrode layer; 310. first electrode;
400. pixel defining layer; 410. pixel defining portion; 420. pixel opening; 430. light-emitting unit;
500. second electrode layer;
600. encapsulation layer;
700. filter layer; 710. light-transmitting hole; 720. filter opening; 721. first filter opening; 721a. first straight edge, 721b. first arc-shaped edge; 722. second filter opening; 722a. second straight edge, 722b. second arc-shaped edge; 723. third filter opening; 730. filter unit; 740. light shielding portion;
T. first virtual quadrangle; X. first direction; Y. second direction; Z. thickness direction.

### DETAILED DESCRIPTION OF EMBODIMENTS

The features and exemplary embodiments of various aspects of the present application will be described in detail below. In the following detailed description, numerous specific details are set forth in order to provide a complete understanding of the present application. The present application may be embodied without some of these specific details. The following description of the embodiments is merely to provide a better understanding of the present application by illustrating examples of the present application. In the accompanying drawings and the following description, at least some well-known structures and techniques are not shown in order to avoid unnecessary obscuring of the present application; and the dimensions of some structures may be exaggerated for clarity. In addition, the features, structures, or characteristics described below may be combined in one or more embodiments in any suitable manner.

In the description of the present application, it should be noted that “a plurality of” means two or more, unless otherwise specified. The orientation or position relationship indicated by the terms “upper”, “lower”, “left”, “right”, “inner”, “outer”, etc. is only for the convenience of describing the present application and simplifying the description, rather than indicating or implying that the device or element referred to must have a particular orientation or be constructed and operated in a particular orientation, and therefore should not be construed as a limitation on the present application. Moreover, the terms “first”, “second”, etc. are merely used for the illustrative purpose, and should not be construed as indicating or implying relative importance.

The orientation terms in the following description all indicate directions shown in the accompanying drawings, and do not limit the specific structure in the embodiments of present application. In the description of the present application, it should be noted that, the terms “mount” and “connect” should be interpreted in a broad sense unless explicitly defined and limited otherwise. For example, they may be a fixed connection, a detachable connection an integral connection; or may refer to a direct connection, or an indirect connection. The specific meanings of the terms mentioned above in the present application can be construed according to specific circumstances.

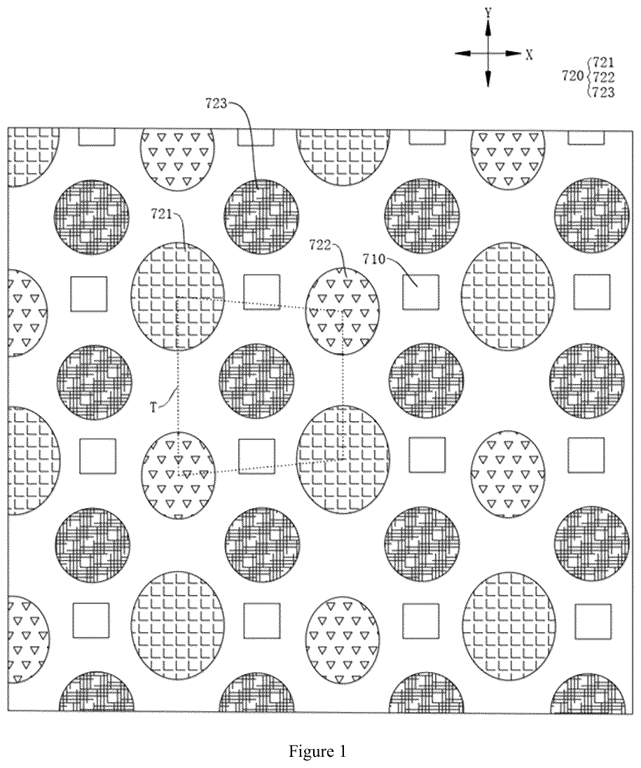

In order to better understand the present application, a filter opening arrangement structure, a display panel and a display device in embodiments of the present application will be described in detail below with reference to FIGS. 1 to 15.

Referring to FIG. 1, FIG. 1 is a schematic diagram of a filter opening arrangement structure according to an embodiment of the present application.

As shown in FIG. 1, an embodiment of a first aspect of the present application provides a filter opening arrangement structure, including a plurality of filter openings 720 and a plurality of light-transmitting holes 710. The filter openings 720 include a first filter opening 721. The first filter opening 721 has an extension dimension in a first direction X smaller than an extension dimension in a second direction Y. The light-transmitting hole 710 is spaced apart from the first filter opening 721, and the light-transmitting hole 710 is located on a side of the first filter opening 721 with a smaller extension dimension. The first direction X intersects the second direction Y. For example, the first direction X and the second direction Y are perpendicular to each other.

The filter opening arrangement structure according to the embodiment of the present application includes a plurality of filter openings 720 and a plurality of light-transmitting holes 710. The filter openings 720 include a first filter opening 721. The first filter opening 721 has a smaller extension dimension in a first direction X, and the first filter opening 721 has a larger extension dimension in a second direction Y, and the space on one side of the first filter opening 721 in the first direction X is relatively large. The light-transmitting hole 710 is spaced apart from the first filter opening 721 in the first direction X, the light-transmitting hole 710 is located on one side of the first filter opening 721 in the first direction X, and the space for providing the light-transmitting hole 710 is relatively large, facilitating an appropriate increase in the size of the light-transmitting hole 710, to increase the distribution area of the light-transmitting hole 710. When the filter opening arrangement structure is applied to a display panel 10, the light transmittance of the display panel 10 can be increased, to improve the use performance of the display panel 10.

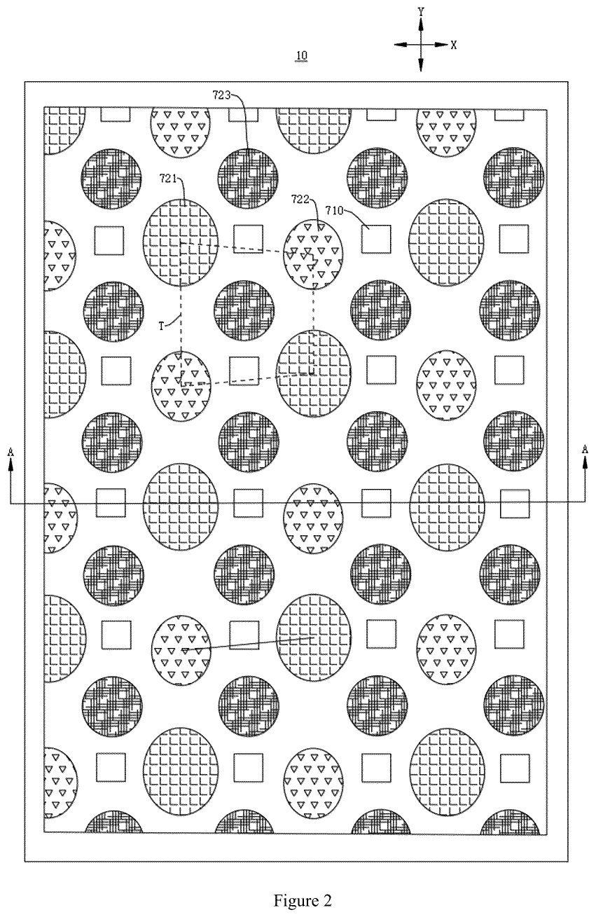

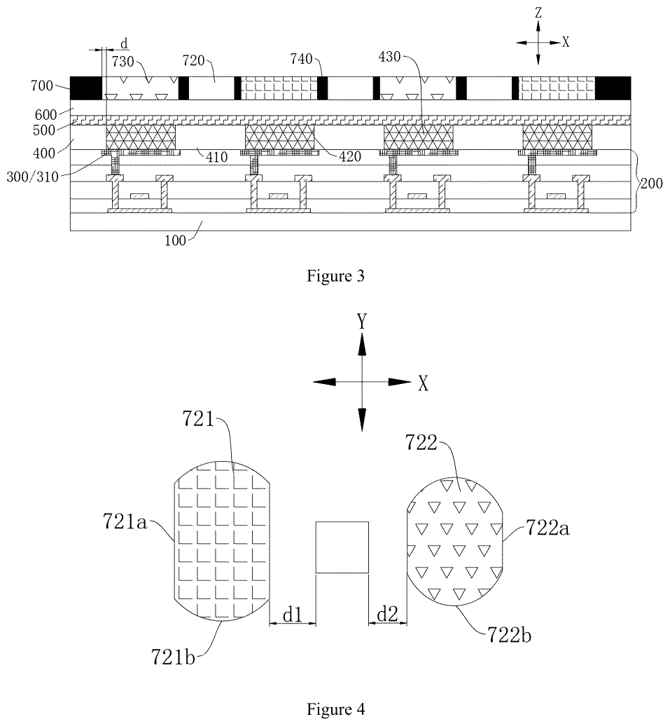

In one embodiment, as shown in FIGS. 2 and 3, the filter opening arrangement structure is used in a display panel 10, the display panel 10 including a filter layer 700. The filter layer 700 includes a light shielding portion 740, and the filter openings 720 and the light-transmitting holes 710 may be provided in the filter layer 700 and penetrate the light shielding portion 740. In one embodiment, the filter openings 720 may be configured to accommodate a plurality of filter units 730 to improve the display effect of the display panel 10. In one embodiment, the filter units 730 may include a plurality of blue filter units, a plurality of red filter units, and a plurality of green filter units. The blue filter units are configured to filter stray light and allow blue light to pass through, the red filter units are configured to filter stray light and allow red light to pass through, and the green filter units are configured to filter stray light and allow green light to pass through, to improve the display effect of the display panel 10.

In one embodiment, the first filter opening 721 may be any of a blue filter opening, a red filter opening and a green filter opening. In one embodiment, the blue filter opening may be configured to accommodate the blue filter unit, the red filter opening may be configured to accommodate the red filter unit, and the green filter opening may be configured to accommodate the green filter unit.

In one embodiment, the display panel 10 further includes a pixel arrangement structure which includes a plurality of sub-pixels, and the arrangement of filter openings 720 in the filter opening arrangement structure matches the arrangement of the plurality of sub-pixels. For example, the pixel arrangement structure includes red sub-pixels, green sub-pixels and blue sub-pixels. The positions of the red sub-pixel and the red filter opening correspond to each other, and light emitted by the red sub-pixel can be emitted through the red filter opening. The positions of the blue sub-pixel and the blue filter opening correspond to each other, and light emitted by the blue sub-pixel can be emitted through the blue filter opening. The positions of the green sub-pixel and the green filter opening correspond to each other, and light emitted by the green sub-pixel can be emitted through the green filter opening.

In one embodiment, the first filter opening 721 may be a blue filter opening or a red filter opening. In the pixel arrangement structure, the number of green sub-pixels is generally larger than the number of blue sub-pixels and the number red sub-pixels, and accordingly the number of green filter openings is larger and the area of the green sub-pixels is smallest, and when the shape of the green sub-pixel changes, the change in a peripheral gap of the green filter opening is relatively small, and thus there is a limited increase in the area of the light-transmitting hole 710; and the areas of the blue sub-pixel and the red sub-pixel are relatively large, and when the shape of the blue sub-pixel or the red sub-pixel changes, the change in a peripheral gap of the blue filter opening or the red filter opening is relatively large, making an increase in the area of the light-transmitting hole 710 relatively large, to facilitate an increase in the light transmittance of the display panel 10. The first filter opening 721 of the embodiment of the present application is a blue filter opening or a red filter opening, and the light-transmitting hole 710 is located on one side of the blue filter opening and/or the red filter opening in the first direction X, and a large space can be provided for providing the light-transmitting hole 710.

In one embodiment, as shown in FIG. 3, the display panel 10 further includes a substrate 100 and a pixel defining layer 400 provided on one side of the substrate 100. The pixel defining layer 400 includes a pixel defining portion 410 and a plurality of pixel openings 420, and a light-emitting unit 430 is accommodated in the pixel opening 420. The display panel 10 further includes a first electrode layer 300. The first electrode layer 300 is located on a side of the pixel defining layer 400 facing the substrate 100, and includes a plurality of first electrodes 310 distributed in an array. Each first electrode 310 is located on the side of a respective light-emitting unit 430 facing the substrate 100. In one embodiment, the display panel 10 further includes a second electrode layer 500. The second electrode layer 500 is located on a side of the pixel defining layer 400 facing away from the substrate 100, and the second electrode layer 500 includes a second electrode located on a side of a respective light-emitting unit 430 facing away from the substrate 100. A plurality of second electrodes may be connected to each other to form a whole layer. The first electrode 310, the light-emitting unit 430 and the second electrode constitute the sub-pixel described above. In one embodiment, the light-emitting unit 430 of the red sub-pixel is configured to emit red light, the light-emitting unit 430 of the green sub-pixel is configured to emit green light, and the light-emitting unit 430 of the blue sub-pixel is configured to emit blue light.

In some embodiments, referring to FIGS. 1-3 together, the filter openings 720 further includes a second filter opening 722. The second filter opening 722 has an extension dimension in the first direction X smaller than an extension dimension in the second direction Y, and the light-transmitting hole 710 is located between the first filter opening 721 and the second filter opening 722 in the first direction X.

In some embodiments, the second filter opening 722 also has a smaller extension dimension in the first direction X, and the light-transmitting hole 710 is located between the first filter opening 721 and the second filter opening 722, and the first filter opening 721 and the second filter opening 722 each provide a clearance for the light-transmitting hole 710, and the distribution area of the light-transmitting hole 710 can be further increased.

In one embodiment, the first filter opening 721 is one of a blue filter opening and a red filter opening, and the second filter opening 722 is the other of the blue filter opening and the red filter opening. As above, the number of blue filter openings and the number of red filter openings are small, their areas are relatively large, and the extension dimensions of the two in the first direction X are controlled to be smaller than the extension dimensions thereof in the second direction Y, and the spacing between the two in the first direction X is relatively large, and the distribution area of the light-transmitting hole 710 disposed between the blue filter opening and the red filter opening can be increased.

In one embodiment, the first filter opening 721 has an elliptical shape, and/or the second filter opening 722 has an elliptical shape. In this way, the first filter opening 721 and/or second filter opening 722 can meet size requirements, and the first filter opening 721 and/or second filter opening 722 are more regular in shape and are easy to manufacture and form.

In one embodiment, the first filter opening 721 has an elliptical shape, meaning that the orthographic projection of the first filter opening 721 in the thickness direction Z of the display panel 10 is elliptical when the filter opening arrangement structure is used in a display panel 10, and the orthographic projection of the first filter opening 721 in the thickness direction Z has a major axis extending in the second direction Y and a minor axis extending in the first direction X, and the first filter opening 721 has an extension dimension in the first direction X smaller than an extension dimension in the second direction Y.

Similarly, the second filter opening 722 has an elliptical shape, meaning that the orthographic projection of the second filter opening 722 in the thickness direction Z is elliptical when the filter opening arrangement structure is used in a display panel 10, and the orthographic projection of the second filter opening 722 in the thickness direction Z has a major axis extending in the second direction Y and a minor axis extending in the first direction X, and the second filter opening 722 has an extension dimension in the first direction X smaller than an extension dimension in the second direction Y.

In one embodiment, there are a plurality of light-transmitting holes 710, each light-transmitting hole 710 being located between a respective first filter opening 721 and an adjacent second filter opening 722. That is, a single light-transmitting hole 710 is provided between a first filter opening 721 and an adjacent second filter opening 722. There are a plurality of light-transmitting holes 710, each light-transmitting hole 710 being located between a different first filter opening 721 and second filter opening 722. The number of light-transmitting holes 710 is large, and when the filter opening arrangement structure is used in a display panel 10, the light transmittance of the display panel 10 can be further increased. Of course, in some other embodiments, at least one light-transmitting hole 710 of the plurality of light-transmitting holes 710 may adopt the arrangement structure of any of the above embodiments, and the remaining light-transmitting holes 710 may adopt a conventional design, which is not specifically limited in the present application.

In some embodiments, there are a plurality of light-transmitting holes 710 in the first direction X, and there are a plurality of light-transmitting holes 710 in the second direction Y. Still further, the plurality of light-transmitting holes 710 are disposed equidistantly in the first direction X, and the plurality of light-transmitting holes 710 are disposed equidistantly in the second direction Y.

In some embodiments, a width of the first filter opening 721 in the first direction X is equal to a width of the second filter opening 722 in the first direction X.

In some embodiments, the first filter opening 721 and the second filter opening 722 have the same width, facilitating the centering of the light-transmitting hole 710 with respect to the first filter opening 721 and the second filter opening 722. That is, the distance from the light-transmitting hole 710 to the first filter opening 721 is equal to the distance from the light-transmitting hole to the second filter opening 722.

Furthermore, when the filter opening arrangement structure is used in a display panel 10, each filter opening 720 and a respective sub-pixel are disposed corresponding to each other in the thickness direction Z, and each sub-pixel and a respective driving unit are disposed corresponding to each other in the thickness direction Z. The driving unit is configured to drive the sub-pixel to emit light for display. Thus, the driving unit and the filter opening 720 are disposed corresponding to each other in the thickness direction Z and most of the area of the driving unit overlaps with the area of the filter opening 720, the distribution area of the driving unit between two adjacent filter openings 720 is relatively small, and the metal wiring area between two adjacent filter openings 720 is relatively small. When the first filter opening 721 and the second filter opening 722 have the same width, the light-transmitting hole 710 is centrally distributed between the first filter opening 721 and the second filter opening 722, to allow the light-transmitting hole 710 to be located in a region where the metal wiring area is small, and facilitating a further increase in the distribution area of the light-transmitting hole 710.

In one embodiment, as shown in FIG. 4, the first filter opening 721 includes two first straight edges 721a disposed opposite to each other in the first direction X and two first arc-shaped edges 721b disposed opposite to each other in the second direction Y. The two first arc-shaped edges 721b are configured to protrude in directions distant from each other, and the two first straight edges 721a and the two first arc-shaped edges 721b define the first filter opening 721.

In some embodiments, the two edges of the first filter opening 721 which are disposed opposite to each other in the first direction X have a rectilinear shape, enabling a further reduction in the size of the first filter opening 721 protruding toward the light-transmitting hole 710, further reducing the distribution size of the first filter opening 721 in the first direction X, and increasing the distribution size of the light-transmitting hole 710.

In one embodiment, when the filter opening arrangement structure is used in a display panel 10, two edges, which are opposite to each other in the first direction X, of the orthographic projection of the first filter opening 721 in the thickness direction Z are first straight edges 721a, and two edges, which are opposite to each other in the second direction Y, of the orthographic projection of the first filter opening 721 in the thickness direction Z are first arc-shaped edges 721b.

In one embodiment, the second filter opening 722 includes two second straight edges 722a disposed opposite to each other in the first direction X and two second arc-shaped edges 722b disposed opposite to each other in the second direction Y. The two second arc-shaped edges 722b are configured to protrude in directions distant from each other, and the two second straight edges 722a and the two second arc-shaped edges 722b define the second filter opening 722.

In some embodiments, the two edges of the second filter opening 722 which are disposed opposite to each other in the first direction X have a rectilinear shape, enabling a further reduction in the size of the second filter opening 722 protruding toward the light-transmitting hole 710, further reducing the distribution size of the second filter opening 722 in the first direction X, and increasing the distribution size of the light-transmitting hole 710.

In one embodiment, when the filter opening arrangement structure is used in a display panel 10, two edges, which are opposite to each other in the first direction X, of the orthographic projection of the second filter opening 722 in the thickness direction Z are second straight edges 722a, and two edges, which are opposite to each other in the second direction Y, of the orthographic projection of the second filter opening 722 in the thickness direction Z are second arc-shaped edges 722b.

In one embodiment, a distance between the two first straight edges 721a of the first filter opening 721 is equal to a distance between the two second straight edges 722a of the second filter opening 722. That is, the width of the first filter opening 721 in the first direction X is equal to the width of the second filter opening 722 in the first direction X, and the light-transmitting hole 710 is centrally distributed with respect to the first filter opening 721 and the second filter opening 722.

In one embodiment, for the first filter opening 721 and the second filter openings 722 adjacent to each other and light-transmitting hole 710 therebetween, a minimum distance d1 from the light-transmitting hole 710 to the first filter opening 721 is equal to a minimum distance d2 from the light-transmitting hole 710 to the second filter opening 722, that is, the light-transmitting hole 710 is centrally arranged with respect to the first filter opening 721 and the second filter opening 722 to increase the distribution area of the light-transmitting hole 710.

In one embodiment, the light-transmitting hole 710 has a polygonal shape, that is, the orthographic projection of the light-transmitting hole 710 in the thickness direction Z has a polygonal shape, and the shape of the light-transmitting hole 710 better fits the shapes of the first filter opening 721 and the second filter opening 722.

In one embodiment, an edge of the light-transmitting hole 710 that faces the second filter opening 722 is parallel to the second straight edge 722a to further increase the distribution area of the light-transmitting hole 710, and/or an edge of the light-transmitting hole 710 that faces the first filter opening 721 is parallel to the first straight edge 721a to further increase the distribution area of the light-transmitting hole 710.

In one embodiment, the light-transmitting hole 710 has a quadrilateral shape, and the light-transmitting hole 710 includes two first edges disposed opposite to each other in the first direction X and two second edges disposed opposite to each other in the second direction Y. The two first edges and the two second edges are alternately connected end-to-end to form the light-transmitting hole 710. One of the two first edges close to the first filter opening 721 is disposed parallel to the first straight edge 721a, and one of the two first edges close to the second filter opening 722 is disposed parallel to the second straight edge 722a. In this way, the light-transmitting hole 710 is more regular in shape and is easy to manufacture and form, and the distribution area of the light-transmitting hole 710 can also be further increased.

In some embodiments, with reference to FIG. 2, the first filter opening 721 is located at a first vertex of a first virtual polygon T, and the second filter opening 722 is located at a second vertex of the first virtual polygon T. The first vertex and the second vertex are disposed alternately and spaced apart from each other, and the first virtual polygon T is a trapezoid. For example, the first virtual polygon T includes an upper base and a lower base parallel to each other and extending in the second direction Y, and a first filter opening 721 and a second filter opening 722 are located at two ends of each of the upper base and the lower base. In this way, the first filter opening 721 and second filter opening 722 can be disposed corresponding to each other in the second direction Y.

In one embodiment, the first virtual polygon T further includes two lateral sides, and the light-transmitting holes 710 may be correspondingly located on the lateral sides.

In one embodiment, the display panel 10 further includes a third filter opening 723. The third filter opening 723 is located within the first virtual polygon T. Two first filter openings 721 and two second filter openings 722 are alternately distributed on the peripheral side of the third filter opening 723, and the third filter opening 723 is misaligned with the light-transmitting holes 710 located on the lateral sides.

In one embodiment, the third filter opening 723 is a green filter opening.

In one embodiment, as shown in FIGS. 1 and 2, the third filter opening 723 has an extension dimension in the first direction X equal to an extension dimension in the second direction Y. For example, the third filter opening 723 is circular.

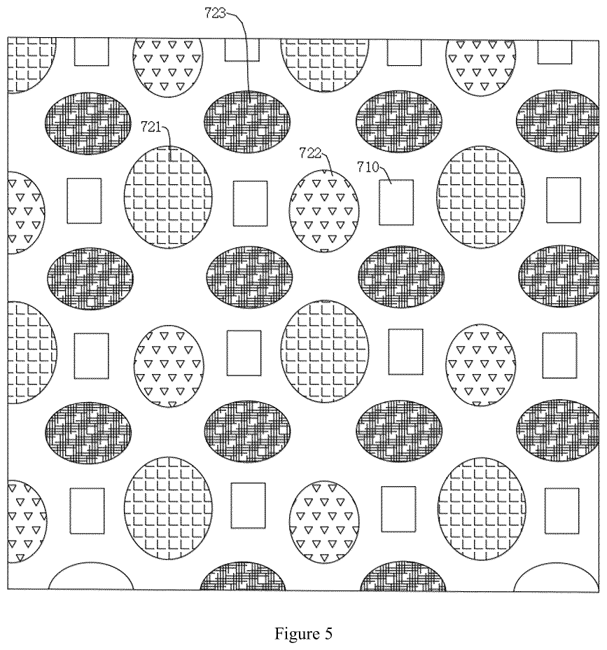

In some embodiments, as shown in FIG. 5, the third filter opening 723 has an extension dimension in the first direction X greater than or equal to an extension dimension in the second direction Y. The third filter opening 723 is located within the first virtual polygon T, the third filter opening 723 is located on one side of the light-transmitting hole 710 in the second direction Y, and the third filter opening 723 has a smaller extension dimension in the second direction Y, and the extension dimension of the light-transmitting hole 710 in the second direction Y can be increased, and the distribution area of the light-transmitting hole 710 can be increased.

In one embodiment, the third filter opening 723 has an elliptical or circular shape, and the third filter opening 723 is more regular in shape and is easy to manufacture and form. In one embodiment, the third filter opening 723 may further include two third arc-shaped edges disposed opposite to each other in the first direction X and two third straight edges disposed opposite to each other in the second direction Y. The two third arc-shaped edges and the two third straight edges are alternately connected end-to-end to form the third filter opening 723.

In some embodiments, a minimum spacing between the filter opening 720 and the light-transmitting hole 710 is in a range from 5 μm to 8 μm. When the minimum spacing between the filter opening 720 and the light-transmitting hole 710 is within the above-mentioned range, it is possible to improve both the problem of reduced distribution area of the light-transmitting hole 710 due to the too large minimum distance between the filter opening 720 and the light-transmitting hole 710 and the problem of excessive difficulty in the manufacturing process due to the too small minimum distance between the filter opening 720 and the light-transmitting hole 710.

In one embodiment, the filter openings 720 include a first filter opening 721 and a second filter opening 722. The first filter opening 721 and the second filter opening 722 are disposed on two sides of the same light-transmitting hole 710. A minimum spacing between the first filter opening 721 and the light-transmitting hole 710 is in a range from 5 μm to 8 μm; and/or a minimum spacing between the second filter opening 722 and the light-transmitting hole 710 is in a range from 5 μm to 8 μm. For example, the minimum spacing between the first filter opening 721 and the light-transmitting hole 710 is 5 μm, 5.4 μm, 5.5 μm, 5.8 μm, 6 μm, 6.2 μm, 6.8 μm, 7 μm, 7.2 μm, 7.5 μm, 8 μm, etc.; and the minimum spacing between the second filter opening 722 and the light-transmitting hole 710 is 5 μm, 5.4 μm, 5.5 μm, 5.8 μm, 6 μm, 6.2 μm, 6.8 μm, 7 μm, 7.2 μm, 7.5 μm, 8 μm, etc.

Referring to FIGS. 2 and 3 together, an embodiment of a second aspect of the present application further provides a display panel 10. The display panel 10 includes a substrate 100 and a filter layer 700. The filter layer 700 is disposed on one side of the substrate 100. The filter layer 700 includes a plurality of filter openings 720 and a plurality of light-transmitting holes 710, and the filter openings 720 and the light-transmitting holes 710 are arranged according to the filter opening arrangement structure of any one of the above embodiments of the first aspect.

In the display panel 10 according to the embodiment of the present application, the filter layer 700 includes a plurality of filter openings 720 and a plurality of light-transmitting holes 710. The filter openings 720 include a first filter opening 721. The first filter opening 721 has a smaller extension dimension in a first direction X, and the first filter opening 721 has a larger extension dimension in a second direction Y, and the space on one side of the first filter opening 721 in the first direction X is relatively large. The light-transmitting hole 710 is spaced apart from the first filter opening 721 in the first direction X, that is, the light-transmitting hole 710 is located on one side of the first filter opening 721 in the first direction X, and the space for providing the light-transmitting hole 710 is relatively large, facilitating an appropriate increase in the size of the light-transmitting hole 710, to increase the distribution area of the light-transmitting hole 710, and the light transmittance of the display panel 10 can be increased, to improve the use performance of the display panel 10.

In one embodiment, the display panel 10 includes a first display area and a second display area. The first display area is a light-transmissive and displayable area for disposing a photosensitive element. For example, the first display area is configured to allow for disposing an infrared sensing element, a fingerprint recognition element, etc. The second display area may be a main display area disposed around at least part of the first display area, and the light-transmitting hole 710 may be located in the first display area to improve the light transmittance of the first display area, to facilitate infrared sensing, fingerprint recognition and other functions. In one embodiment, the first display area may be provided with a plurality of light-transmitting holes 710. The plurality of light-transmitting holes 710 may be evenly distributed within the first display area.

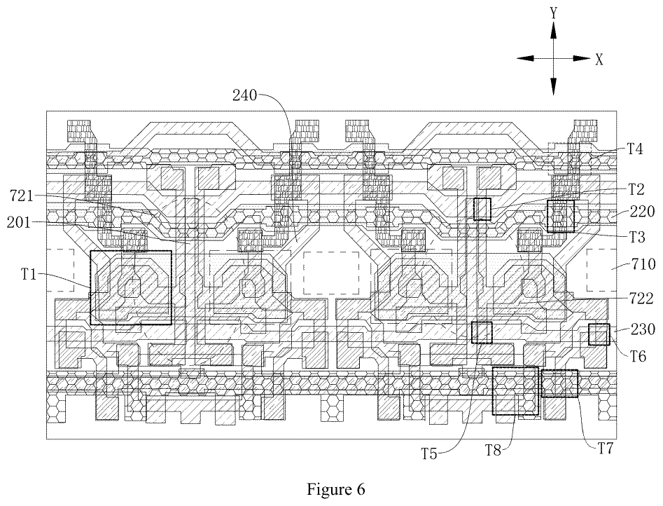

In some embodiments, as shown in FIGS. 2 and 6, the filter openings 720 further include a second filter opening 722. The second filter opening 722 has an extension dimension in the first direction X smaller than an extension dimension in the second direction Y. A plurality of first filter openings 721 and a plurality of second filter openings 722 are disposed in an array, and an orthographic projection of the light-transmitting hole 710 on the substrate 100 is located between an orthographic projection of the first filter opening 721 on the substrate 100 and an orthographic projection of the second filter opening 722 on the substrate 100. The distribution area of the light-transmitting hole 710 can be further increased, and the distribution of the plurality of first filter openings 721 and the plurality of second filter openings 722 in an array can guarantee the display effect of the display panel.

In one embodiment, the display panel 10 further includes a plurality of first power supply signal lines 201. An orthographic projection of the first power supply signal line 201 on the substrate 100 is configured to extend in the second direction Y. Orthographic projections of a plurality of first power supply signal lines 201 on the substrate 100 are disposed side by side in the first direction X. In one embodiment, the first power supply signal line 201 may provide driving signals for driving units of a plurality of sub-pixels distributed in the same column and spaced apart from each other in the second direction Y, the first power supply signal line 201 and the plurality of driving units in the same column are then disposed corresponding to each other, and the first power supply signal line 201 are disposed corresponding to the plurality of sub-pixels in the same column and the plurality of filter openings 720.

In one embodiment, the orthographic projection of at least one of the first filter openings 721 on the substrate 100 at least partially overlaps with the orthographic projection of one of the first power supply signal lines 201 on the substrate 100, and the orthographic projection of the first filter opening 721 on the substrate 100 is disposed symmetrically with respect to the orthographic projection of the first power supply signal line 201 on the substrate 100, and/or the orthographic projection of at least one of the second filter openings 722 on the substrate 100 at least partially overlaps with the orthographic projection of one of the first power supply signal lines 201 on the substrate 100, and the orthographic projection of the second filter opening 722 on the substrate 100 is disposed symmetrically with respect to the orthographic projection of the first power supply signal line 201 on the substrate 100 the orthographic projection of the substrate 100 is disposed symmetrically with respect to the orthographic projection of the first power supply signal line 201 on the substrate 100.

In some embodiments, the metal wiring area at the position of the first power supply signal line 201 is relatively large, and the orthographic projection of the first filter opening 721 on the substrate 100 is disposed symmetrically with respect to the orthographic projection of the first power supply signal line 201 on the substrate 100, and the first filter opening 721 can be disposed corresponding to a region where the metal wiring area is large, the light-transmitting hole 710 can be disposed corresponding to a region where the metal wiring area is small, and the distribution area of the light-transmitting hole 710 can be increased.

Likewise, the orthographic projection of the second filter opening 722 on the substrate 100 is disposed symmetrically with respect to the orthographic projection of the first power supply signal line 201 on the substrate 100, and the second filter opening 722 can be disposed corresponding to a region where the metal wiring area is large, the light-transmitting hole 710 can be disposed corresponding to a region where the metal wiring area is small, and the distribution area of the light-transmitting hole 710 can be increased.

In one embodiment, the orthographic projections, on the substrate 100, of the first filter openings 721 and the second filter openings 722, which are located in the same column and distributed spaced apart from each other in the second direction Y, are disposed symmetrically with respect to the orthographic projection of the first power supply signal line 201 on the substrate 100. In this way, the arrangement of the first filter openings 721 and the second filter openings 722 is made more regular, and the distribution area of the light-transmitting hole 710 can also be further increased.

In one embodiment, the first power supply signal line 201 is a driving power supply voltage signal line (ELVDD).

In some embodiments, as shown in FIG. 3, the display panel 10 further includes a pixel defining layer 400. The pixel defining layer 400 is located between the substrate 100 and the filter layer 700, and the pixel defining layer 400 is provided with a plurality of pixel openings 420. The pixel openings 420 is disposed corresponding to the filter openings 720, and an orthographic projection of the pixel opening 420 on the substrate 100 at least partially overlaps with the orthographic projection of the filter opening 720 on the substrate 100.

In one embodiment, as described above, the sub-pixel includes a light-emitting unit 430, and the pixel opening 420 is configured to accommodate the light-emitting unit 430. The orthographic projection of the pixel opening 420 on the substrate 100 overlaps with the orthographic projection of the filter opening 720 on the substrate 100, and light emitted by the light-emitting unit 430 in the pixel opening 420 can be emitted more through the filter opening 720 to improve the display effect of the display panel 10.

In one embodiment, the orthographic projection of the pixel opening 420 on the substrate 100 is located within the orthographic projection of the filter opening 720 on the substrate 100 to enable more light to be emitted through the filter opening 720, further improving the display effect of the display panel 10.

In one embodiment, as shown in FIGS. 2 and 7, the orthographic projection of the filter opening 720 on the substrate 100 is defined as a projection I, and the orthographic projection of the pixel opening on the substrate 100 is defined as a projection II. An edge of the projection I is disposed equidistantly from an edge of the projection II. By an edge of the projection I being disposed equidistantly from an edge of the projection II, it is meant that the projection II is located within the projection I, and the distances from different positions of the edge of the orthographic projection II to respective positions of the edge of the projection I are equal, and the shape of the pixel opening better fits the shape of the filter opening 720, and more light can be emitted through the filter opening 720. The position of the pixel opening 420 is indicated by a dashed line in FIG. 7. The position of the pixel opening 420 is the position of the projection II, and the position of the filter opening 720 is the position of the projection I.

For example, when the filter openings 720 include a first filter opening 721, a second filter opening 722 and a third filter opening 723, the pixel openings 420 include a first pixel opening, a second pixel opening and a third pixel opening. An edge of an orthographic projection of the first filter opening 721 on the substrate 100 is disposed equidistantly from an edge of an orthographic projection of the first pixel opening on the substrate 100. For example, when the orthographic projection of the first filter opening 721 on the substrate 100 has an elliptical shape, the orthographic projection of the first pixel opening on the substrate 100 may have an elliptical shape. An edge of an orthographic projection of the second filter opening 722 on the substrate 100 is disposed equidistantly from an edge of an orthographic projection of the second pixel opening on the substrate 100. For example, when the orthographic projection of the second filter opening 722 on the substrate 100 has an elliptical shape, the orthographic projection of the second pixel opening on the substrate 100 may have an elliptical shape. An edge of an orthographic projection of the third filter opening 723 on the substrate 100 is disposed equidistantly from an edge of an orthographic projection of the third pixel opening on the substrate 100. For example, when the orthographic projection of the third filter opening 723 on the substrate 100 has an elliptical shape, the orthographic projection of the third pixel opening on the substrate 100 may have an elliptical shape.

In some embodiments, as described above, the display panel 10 further includes a driving device layer 200. The driving device layer 200 includes a plurality of driving units. As above, the orthographic projection of the light-transmitting hole 710 on the substrate 100 is defined as a first orthographic projection located between orthographic projections of two of the driving units on the substrate 100.

In some embodiments, a single driving unit is configured to drive a single sub-pixel of the display panel 10 for display. Of course, in other embodiments, a single driving unit may be configured to drive a plurality of sub-pixels of the display panel for display. The metal wiring in the driving unit is generally dense. In the embodiments of the present application, the orthographic projection of the light-transmitting hole 710 on the substrate 100 is disposed between the orthographic projections of two adjacent driving units on the substrate 100, and it is possible to reduce the influence of the light-transmitting hole 710 on the wiring in the driving unit, and simplify the wiring structure of the display panel 10. Moreover, the metal wiring area between two adjacent driving units is small, and the distribution area of the light-transmitting hole 710 can be increased, and the light transmittance of the display panel 10 can be increased, to improve the use performance of the display panel 10.

In one embodiment, the driving unit may include a plurality of thin film transistors and at least one of capacitors. The driving unit may be any one of a 2T1C circuit, a 7T1C circuit, a 7T2C circuit, an 8T1C circuit, and a 9T1C circuit. In the embodiments of the present application, “2T1C circuit” is a pixel circuit in which the driving unit includes two thin film transistors (T) and one capacitor (C), and the same applies to the “7T1C circuit”, the “7T2C circuit,” the “8T1C circuit”, the “9T1C circuit”, etc. The driving unit may further include a different number of thin film transistors and a different number of capacitors as long as the driving unit can drive the sub-pixel for display.

In some embodiments, as shown in FIGS. 2-8, the driving unit includes a driving transistor T1, one first orthographic projection is located between orthographic projections of driving transistors T1 of two driving units on the substrate 100.

The driving unit includes a plurality of thin film transistors. For example, the driving unit includes a data write transistor T2, a first reset transistor T4, and a driving transistor T1. The distribution area of the driving transistor T1 is generally large, and the space on the peripheral side of the driving transistor T1 is large. In the embodiments of the present application, the first orthographic projection is disposed within the orthographic projections of the driving transistors T1 of two adjacent driving units on the substrate 100, and it is possible to accommodate the light-transmitting hole 710 by using a large gap between the two adjacent driving transistors T1, and to increase the distribution area of the light-transmitting hole 710.

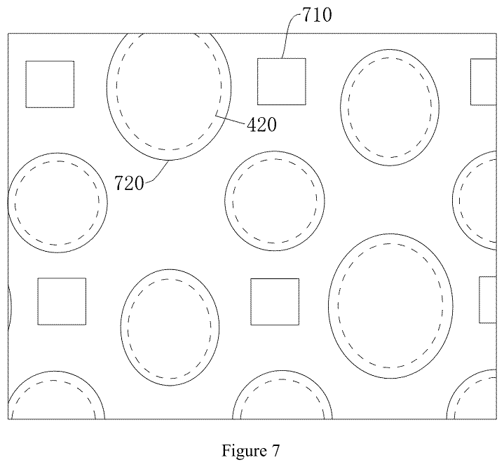

In one embodiment, the plurality of thin film transistors of the driving unit further include a threshold compensation transistor T3, a bias transistor T8, a first light emission control transistor T5, a second light emission control transistor T6 and a second reset transistor T7. The thin film transistors and the capacitor of the driving unit are connected in the manner shown in FIG. 8, and the positions of the thin film transistors are indicated by frame lines in FIG. 6.

In other embodiments, as above, the driving unit may be any one of a 2T1C circuit, a 7T1C circuit, a 7T2C circuit, and a 9T1C circuit. Other thin film transistors may also be included in the driving unit, and the thin film transistors of the driving unit may be electrically connected to each other in other manners.

In one embodiment, the display panel 10 includes a first electrode 310, and a driving transistor T1 is electrically connected to the first electrode 310. In the embodiments of the present application, the driving transistor T1 is a thin film transistor electrically connected to the first electrode 310, and the driving transistor T1 is connected to the first electrode 310 to send a signal to the first electrode 310.

In some embodiments, as shown in FIG. 6, the driving device layer 200 further includes a second signal line 230. An orthographic projection of the second signal line 230 on the substrate 100 is configured to extend in the first direction X. In one embodiment, the second signal line 230 may be located on one side, in the second direction Y, of a plurality of driving transistors T1, which are located in the same row and arranged in the first direction X.

In one embodiment, the driving device layer 200 further includes a first signal line 220. An orthographic projection of the first signal line 220 on the substrate 100 and an orthographic projection of the second signal line 230 on the substrate 100 both extend in the first direction X. The orthographic projection of the first signal line 220 on the substrate 100 and the orthographic projection of the second signal line 230 on the substrate 100 are disposed side by side in the second direction Y. A plurality of driving transistors T1 disposed in the same row in the first direction X are located between the first signal line 220 and adjacent the second signal line 230, the first orthographic projection is located between orthographic projections of two driving transistors T1 on the substrate 100, and the first orthographic projection is located between the orthographic projection of the adjacent first signal line 220 on the substrate 100 and the orthographic projection of the second signal line 230 on the substrate 100.

In some embodiments, the orthographic projection of the first signal line 220 on the substrate 100 and the orthographic projection of the second signal line 230 on the substrate 100 are spaced apart from each other and disposed side by side in the second direction Y. At least a portion of the driving unit is located between and electrically connected to the first signal line 220 and adjacent the second signal line 230. The orthographic projection of the driving transistor T1 on the substrate 100 is located between the orthographic projection of the adjacent first signal line 220 on the substrate 100 and the orthographic projection of the second signal line 230 on the substrate 100, and the orthographic projections of the plurality of driving transistors T1 on the substrate 100 are located between the orthographic projection of the adjacent first signal line 220 on the substrate 100 and the orthographic projection of the second signal line 230 on the substrate 100 and are distributed spaced apart from each other in the first direction X. The metal wiring density between the first signal line 220 and the second signal line 230 on two sides of the plurality of driving transistors T1 is low, disposing the first orthographic projection between the first signal line 220 and the second signal line 230 which are adjacent to each other and connected to a plurality of driving units distributed in the same row in the first direction X can further increase the distribution area of the light-transmitting hole 710.

In one embodiment, the orthographic projections of two driving transistors T1 on the substrate 100 are respectively disposed on two sides of the first orthographic projection in the first direction X.

In one embodiment, the symmetrical distribution of the driving transistors T1 located on two sides of the light-transmitting hole 710 in the first direction X can simplify the metal wiring structure of the driving device layer 200 while also ensuring that the characteristics of each driving transistor are the same, to ensure the display effect.

In one embodiment, the number of first signal lines 220 and the number of second signal lines 230 are both two or more. The first signal line 220 and the second signal line 230 and the driving units disposed in the same row are connected to each other, that is, the first signal line 220, the second signal line 230 and the driving units disposed in the same row are correspondingly disposed, and the light-transmitting hole 710 is located between the first signal line 220 and the second signal line 230 which are adjacent to each other and connected to the driving units disposed in the same row.

In some embodiments, as shown in FIGS. 6 and 9, the driving transistor T1 includes a semiconductor layer 211. The semiconductor layer 211 includes a source region 211a, a drain region 211b, and a channel region 211c located between the source region 211a and the drain region 211b. The channel region 211c is configured to protrude with respect to the source region 211a and the drain region 211b in the second direction Y.

In some embodiments, the channel region 211c is configured to protrude with respect to the source region 211a and the drain region 211b in a direction away from the second signal line 230, and the semiconductor layer 211 is generally II-shaped. On the basis of ensuring the performance of the driving transistor T1, the extension dimension of the semiconductor layer 211 in the first direction X can be reduced, to increase the spacing between two driving transistors T1 adjacent to each other in the first direction X, and increasing the distribution area of the light-transmitting hole 710.

In one embodiment, when the display panel 10 includes the second signal line 230, the orthographic projection of the channel region 211c on the substrate 100 is configured to protrude in a direction away from the orthographic projection of the second signal line 230 on the substrate 100, to make the layout of the semiconductor layer 211 more scientific and reasonable.

In one embodiment, the orthographic projection of the drain region 211b on the substrate 100 is located between the orthographic projection of the source region 211a on the substrate 100 and the first orthographic projection, and in the second direction Y, a distance between the orthographic projection of the source region 211a on the substrate 100 and the orthographic projection of the second signal line 230 on the substrate 100 is greater than a distance between the orthographic projection of the drain region 211b on the substrate 100 and the orthographic projection of the second signal line 230 on the substrate 100. Of course, in some embodiments, the orthographic projections of the two driving transistors T1 on the substrate 100 are respectively located on opposite sides of the first orthographic projection in the first direction X, and the distance between the orthographic projection of the source region 21 la of at least one of the driving transistors T1 on the substrate 100 and the orthographic projection of the second signal line 230 on the substrate 100 in the second direction Y is greater than the distance between the orthographic projection of the drain region 211b on the substrate 100 and the orthographic projection of the second signal line 230 on the substrate 100 in the second direction Y. That is, it is possible to define the source region 211a and the drain region 211b of only one of the driving transistors T1, to increase the distribution area of the light-transmitting hole 710.

In the above embodiment, the drain region 211b is closer to the light-transmitting hole 710 than the source region 211a, and the distance between the drain region 211b and the second signal line 230 is shorter, and the drain region 211b can provide clearance for the light-transmitting hole 710, further increasing the distribution area of the light-transmitting hole 710.

In one embodiment, the semiconductor layers 211 of the driving transistors T1 located on two sides of the same light-transmitting hole 710 are symmetrically distributed about the light-transmitting hole 710. For example, the orthographic projections, on the substrate 100, of the semiconductor layers 211 of the driving transistors T1 located on the two sides of the same light-transmitting hole 710 are symmetrically distributed about a first reference line where the geometric center of the first orthographic projection is located. When the light-transmitting hole 710 is a regular polygon, the orthographic projections, on the substrate 100, of the semiconductor layers 211 of the driving transistors T1 located on two sides of the same first orthographic projection are symmetrically distributed about the first reference line which extends in the second direction Y and passes through the geometric center of the first orthographic projection, to simplify the wiring structure of the driving device layer 200. The second direction Y is perpendicular to the first direction X.

In some embodiments, as shown in FIGS. 6, 8 and 10, the driving unit further includes a first reset transistor T4 and a connecting wire 240. The driving transistor T1 is connected to the first reset transistor T4 via the connecting wire 240, and an orthographic projection of the connecting wire 240 on the substrate 100 is disposed around part of the first orthographic projection.

In some embodiments, the driving unit further include a first reset transistor T4. The first reset transistor T4 may reset a gate of the driving transistor T1. The first reset transistor T4 and the driving transistor T1 are connected to each other via the connecting wire 240, and the orthographic projection of the connecting wire 240 on the substrate 100 is disposed around part of the light-transmitting hole 710, and the connecting wire 240 can provide clearance for the light-transmitting hole 710, further increasing the distribution area of the light-transmitting hole 710.

In one embodiment, the orthographic projection of the connecting wire 240 on the substrate 100 is configured to be bent in a direction away from the first orthographic projection, to further provide clearance for the light-transmitting hole 710 to increase the distribution area of the light-transmitting hole 710.

In one embodiment, connecting wires 240 of the driving units located on the two sides of the light-transmitting hole 710 are symmetrically distributed to simplify the wiring structure within the driving device layer 200.

The connecting wire 240 may be shaped in a variety of ways. For example, the connecting wire 240 may extend along an arc-shaped path. For example, the shape of the connecting wire 240 fits the shape of the edge of the light-transmitting hole 710.

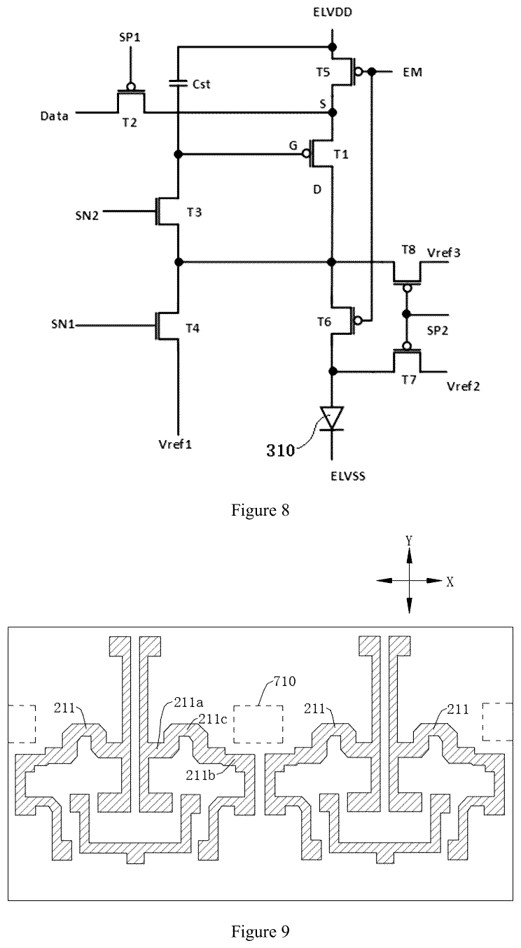

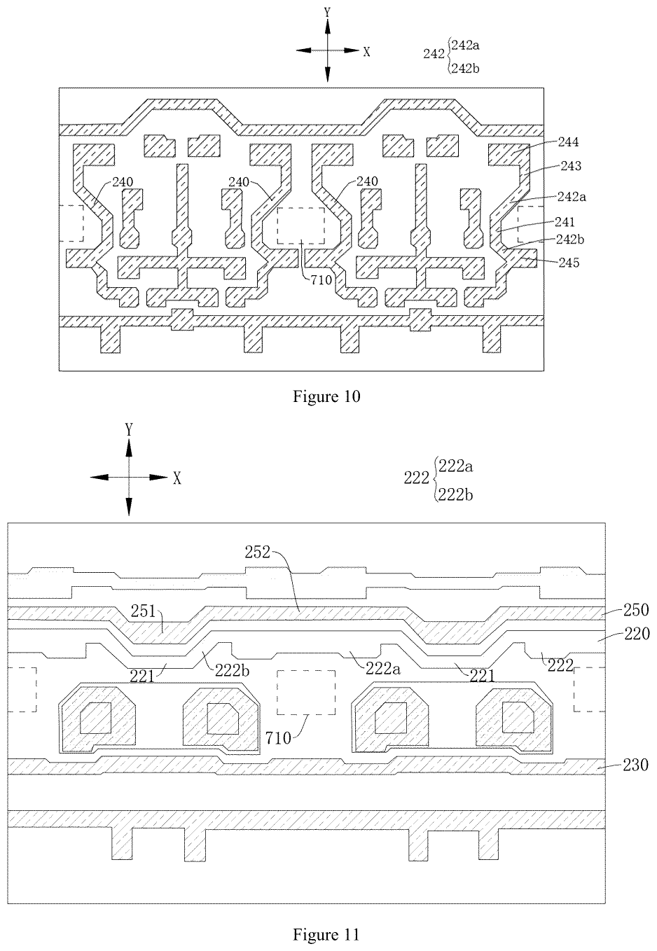

In some embodiments, referring to FIG. 10, the connecting wire 240 includes a first segment 241 and two inclined segments 242 connected to two ends of the first segment 241. Orthographic projections of first segments 241 of two connecting wires 240 on the substrate 100 are disposed on the two sides of the first orthographic projection in the first direction X. The first segment 241 extends in the second direction Y, and orthographic projections, on the substrate 100, of the two inclined segments 242 connected to the first segment 241 in the second direction Y are disposed obliquely in a direction close to the first orthographic projection.

In some embodiments, the connecting wire 240 includes a first segment 241 and two inclined segments 242, and the inclined segments 242 can provide clearance for the wiring which is located at the orthographic projections of the inclined segments on the substrate 100 and faces away from the first orthographic projection, and the shape of the connecting wire 240 can better fit the shape of the light-transmitting hole 710. The first segment 241 and the two inclined segments 242 can be configured to extend in a straight line to facilitate the manufacturing and formation of the connecting wire 240.

In one embodiment, the connecting wire 240 further includes a second segment 243 extending in the second direction Y, the two inclined segments 242 include a first inclined segment 242a, the first inclined segment 242a being connected between the first segment 241 and the second segment 243, and the first segment 241 is electrically connected to the first reset transistor T4 via the second segment 243.

In some embodiments, the second segment 243 is provided on a side of the first inclined segment 242a facing away from the first segment 241, and the length of the connecting wire 240 can be increased, facilitating the electrical connection of the connecting wire 240 to the first reset transistor T4.

In one embodiment, a side of the second segment 243 facing away from the first inclined segment 242a is further connected to a third segment 244. The third segment 244 is configured to extend in the first direction X, and third segments 244 of two connecting wires 240 located on two sides of the light-transmitting hole 710 extend from respective second segments 243 in directions away from each other. An end of the third segment 244 facing away from the second segment 243 is electrically connected to the first reset transistor T4. By adding the third segment 244, the length of the connecting wire 240 can be further increased, facilitating the electrical connection of the connecting wire 240 to the first reset transistor T4.

In one embodiment, the connecting wire 240 further includes a fourth segment 245 extending in the first direction X, and the two inclined segments 242 further include a second inclined segment 242b connected between the first segment 241 and the fourth segment 245. The fourth segment 245 is electrically connected to the driving transistor T1. By adding the fourth segment 245, the connecting wire 240 can better surround the light-transmitting hole 710 and the length of the connecting wire 240 is increased, facilitating the electrical connection of the connecting wire 240 to the driving transistor T1.

In some embodiments, as shown in FIGS. 6 and 11-13, the driving device layer 200 further includes the first signal line 220 and the second signal line 230 described above. The orthographic projection of the first signal line 220 on the substrate 100 and the orthographic projection of the second signal line 230 on the substrate 100 are disposed side by side in the second direction Y. The first orthographic projection is located between the orthographic projection of the first signal line 220 on the substrate 100 and the orthographic projection of the second signal line 230 on the substrate 100.

In some embodiments, the first orthographic projection is located between the orthographic projection of the first signal line 220 on the substrate 100 and the orthographic projection of the second signal line 230 on the substrate 100 to reduce the influence of the first signal line 220 and the second signal line 230 on the light transmittance of the light-transmitting hole 710.

In one embodiment, a plurality of driving units disposed in the same row in the first direction X are connected to the same first signal line 220 and the same second signal line 230, the first orthographic projection is located between the orthographic projections, on the substrate 100, of two driving units adjacent to each other in the first direction X, and the first orthographic projection is located between the orthographic projection of the adjacent first signal line 220 on the substrate 100 and the orthographic projection of the second signal line 230 on the substrate 100, to further increase the distribution area of the light-transmitting hole 710.

In some embodiments, the first signal line 220 and the second signal line 230 may be located in the same film layer or in different film layers. For example, the first signal line 220 and the second signal line 230 are located in different film layers, to reduce the distribution area of the wiring in the same film layer. When lines located in different film layers are electrically connected, the connection can be made through vias.

In one embodiment, the first signal line 220 is a scanning signal line and the second signal line 230 is a light emission control signal line. A large gap between the scanning signal line and the light emission control signal line which are connected to the driving units in the same row can increase the distribution area of the light-transmitting hole 710.

In one embodiment, the driving unit includes a threshold compensation transistor T3. The threshold compensation transistor T3 is electrically connected to the first signal line 220. That is, the first signal line 220 is a scanning signal line connected to the threshold compensation transistor T3, and a gap between the scanning signal line and the light emission control signal line is large, and the distribution area of the light-transmitting hole 710 can be increased.

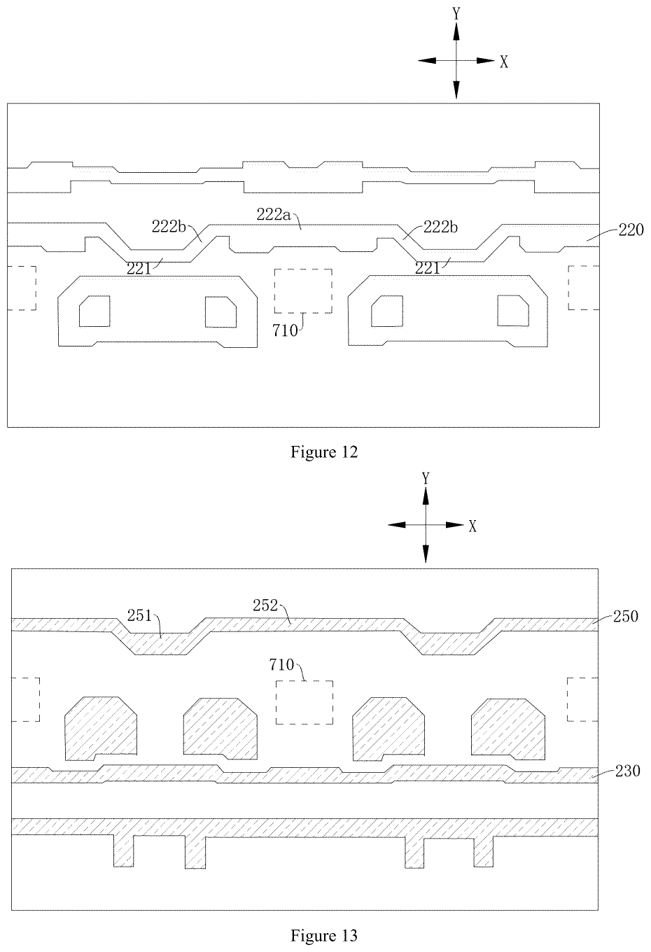

In one embodiment, the driving device layer 200 further includes a voltage reference line Vref, a power supply signal line ELVDD, a low-level power supply signal line ELVSS, and a data line Data. The driving device layer 200 includes a first scanning signal line SN1 and a second scanning signal line SN2. The first scanning signal line SN1 is electrically connected to the first reset transistor T4 to control the switching of the first reset transistor T4. The second scanning signal line SN2 is electrically connected to the threshold compensation transistor T3, and the second scanning signal line SN2 is configured to control the switching of the threshold compensation transistor T3. The first signal line 220 described above may be the second scanning signal line SN2. Referring to FIG. 12, the first scanning signal line SN1 is disposed in the same layer as the second scanning signal line SN2, and the first scanning signal line SN1 is configured to extend in the first direction. The first scanning signal line SN1 is located on a side of the second scanning signal line SN2 away from a light-transmitting area TA, which is not marked in the figures.

In one embodiment, the light emission control signal line EM is connected to the first light emission control transistor T5 and the second light emission control transistor T6.

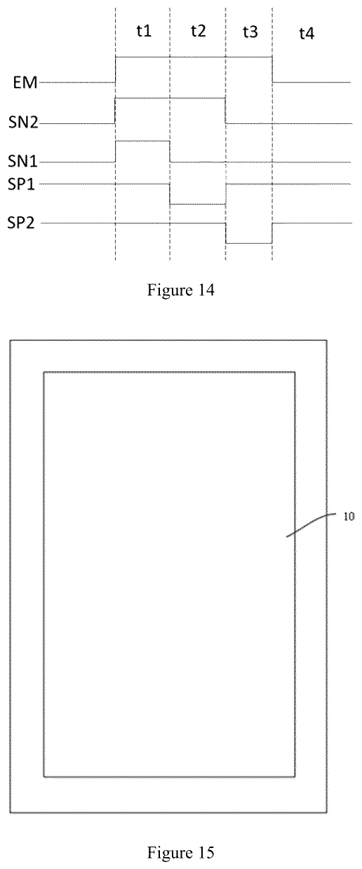

In one embodiment, as shown in FIGS. 8 and 14, the driving device layer 200 further includes a third scanning signal line SP1 and a fourth scanning signal line SP2. The voltage reference line Vref includes a first voltage reference line Vref1, a second voltage reference line Vref2 and a third voltage reference line Vref3. During operation of the display panel, in stages t1 to t3, the light emission control signal line EM is at a high level, the first light emission control transistor T5 and the second light emission control transistor T6 are in a closed state, a signal of the driving power supply voltage signal line ELVDD does not enter the first electrode 310, and the sub-pixel does not emit light. In stages t1 and t2, the second scanning signal line SN2 is at a high level, the threshold compensation transistor T3 is turned on, and the gate G and a drain D of the driving transistor T1 are connected. Moreover, in stage t1, the first scanning signal line SN1 is at a high level, the first reset transistor T4 is turned on, the first voltage reference signal line Vref1 is connected to the gate G of the driving transistor T1, to reset the gate G of the driving transistor T1. In stage t2, the third scanning signal line SP1 is at a low level, the data write transistor T2 is turned on, and the data line Data is connected to the data write transistor T2, a source S and the drain D of the driving transistor T1 and the gate G of the driving transistor T1. In stage t3, the fourth scanning signal line SP2 is at a low level, the second reset transistor T7 and the bias transistor T8 are turned on, the second voltage reference signal line Vref2 is connected to the first electrode 310, and the third voltage reference signal line Vref3 is connected to the drain D of the driving transistor T1. In stage t4, the light emission control signal line EM is at a low level, the first light emission control transistor T5 and the second light emission control transistor T6 are in a turned-on state, the driving power supply voltage signal line ELVDD is connected to the first electrode 310, and the sub-pixel emits light. In some embodiments, the bias transistor T8 may be two thin film transistors connected in series, which can reduce leakage current.

The first signal line 220 may be shaped in a variety of ways. For example, the first signal line 220 extends rectilinearly in the first direction X.

In some embodiments, referring to FIG. 11 or 12, the first signal line 220 includes a first extension portion 221 and a first bent portion 222 connected to each other. An orthographic projection of the first bent portion 222 on the substrate 100 is located on one side of the first orthographic projection, and the orthographic projection of the first bent portion 222 on the substrate 100 is configured to protrude in the direction away from the first orthographic projection.

In some embodiments, the orthographic projection of the first bent portion 222 on the substrate 100 is configured to protrude in the direction away from the first orthographic projection with respect to an orthographic projection of the first extension portion 221 on the substrate 100, and the first bent portion 222 can provide clearance for the light-transmitting hole 710 to further increase the distribution area of the light-transmitting hole 710.

In one embodiment, the first bent portion 222 includes a first section 222a and second sections 222b. An orthographic projection of the first section 222a on the substrate 100 is located on a side, which faces away from the first orthographic projection, of the orthographic projection of the first extension portion 221 on the substrate 100. The two second sections 222b are respectively connected to two ends of the second section 222b, and the second section 222b is connected to the first section 222a and the first extension portion 221. Part of the first orthographic projection is located between orthographic projections of the two second sections 222b on the substrate 100.

In these embodiments, the first bent portion 222 includes the first section 222a and the second sections 222b, the two second sections 222b being connected to two sides of the first section 222a, the first bent portion 222 protrudes in a generally trapezoidal shape, and part of the first orthographic projection is located between the orthographic projections of the two second sections 222b on the substrate 100, and the first bent portion 222 can better provide clearance for the light-transmitting hole 710 to further increase the area of the light-transmitting hole 710.

In one embodiment, the first extension portion 221 and the first bent portion 222 are alternately connected to each other in the first direction X. When there are a plurality of light-transmitting holes 710, a plurality of first bent portions 222 can provide clearance for the plurality of light-transmitting holes 710.

In some embodiments, the driving device layer 200 further includes a third signal line 250. An orthographic projection of the third signal line 250 on the substrate 100 is located on a side, which faces away from the first orthographic projection, of the orthographic projection of the first signal line 220 on the substrate 100, and the third signal line 250 includes a second extension portion 251 and a second bent portion 252 connected to each other. An orthographic projection of the second bent portion 252 on the substrate 100 is located on a side, which faces away from the first orthographic projection, of the orthographic projection of the first bent portion 222 on the substrate 100, and the orthographic projection of the second bent portion 252 on the substrate 100 is configured to protrude in the direction away from the first orthographic projection.

In the embodiments of the present application, the shape of the orthographic projection, on the substrate 100, of the third signal line 250 located on a side, which faces away from the first orthographic projection, of the orthographic projection of the first signal line 220 on the substrate 100 fits the shape of the first signal line 220, and it is possible to improve the problem of the first signal line 220 and the third signal line 250 being likely to be short-circuited due to their overlap.

In one embodiment, an orthographic projection of the second extension portion 251 on the substrate 100 is disposed parallel to the orthographic projection of the first extension portion 221 on the substrate 100, and/or the orthographic projection of the first bent portion 222 on the substrate 100 is disposed equidistantly from the orthographic projection of the second bent portion 252 on the substrate 100, and the shape of the first signal line 220 better fits the shape of the third signal line 250.

In one embodiment, the third signal line 250 and the first signal line 220 are located in different film layers. When the third signal line 250 and the first signal line 220 are located in different film layers, the spacing between the third signal line 250 and the first signal line 220 can be minimized, to improve the problem of too large spacing due to the limitation of the manufacturing process caused by the third signal line 250 and the first signal line 220 being located in the same layer, and the first signal line 220 can be as close to the third signal line 250 as possible to provide clearance for the light-transmitting hole 710.

In one embodiment, the third signal line 250 and the second signal line 230 are located in the same film layer. In this way, the third signal line 250 and second signal line 230 can be manufactured and formed in the same process step, and the manufacturing process of the display panel can be simplified.

In one embodiment, the driving unit includes a data write transistor T2. The third signal line 250 is electrically connected to the data write transistor T2. In other embodiments, the third signal line 250 may also be another signal line.

In one embodiment, in any one of the above embodiments, the light-transmitting hole 710 is configured to transmit ambient light, and there may be a plurality of light-transmitting holes 710, to further increase the light transmittance of the display panel.

In one embodiment, an encapsulation layer 600 is further provided on a side of the second electrode layer 500 facing away from the substrate 100. The encapsulation layer 600 is configured to provide sealing protection for the light-emitting unit 430. In one embodiment, the filter layer 700 is located on a side of the encapsulation layer 600 facing away from the substrate 100, and other film layers such as a touch layer may be provided between the filter layer 700 and the encapsulation layer 600.

As shown in FIG. 15, an embodiment of a third aspect of the present application further provides a display device, including the display panel 10 of any one of the above embodiments of the second aspect. Since the display device according to the embodiment of the third aspect of the present application includes the display panel 10 of any one of the above embodiments of the second aspect, the display device according to the embodiment of the second aspect of the present application has the beneficial effects of the display panel 10 of any one of the above embodiments of the first aspect, and will not be described in detail here.

The display device in the embodiments of the present application includes, but is not limited to, a cell phone, a personal digital assistant (PDA), a tablet computer, an e-book, a television, an access control system, a smart landline phone, a console, and other devices having a display function.

Although the present application has been described with reference to the embodiments, various modifications can be made, and equivalents can be provided to substitute for the components thereof without departing from the scope of the present application. In particular, the features mentioned in the embodiments can be combined in any manner, provided that there is no structural conflict. The present application is not limited to the specific examples disclosed herein but includes all the embodiments that fall within the scope of the claims.

What is claimed is:

1. A filter opening arrangement structure, comprising:
a plurality of filter openings; and
a plurality of light-transmitting holes, wherein the filter openings comprise a first filter opening having an extension dimension in a first direction smaller than an extension dimension in a second direction, the light-transmitting hole is spaced apart from the first filter opening, and the light-transmitting hole is located on a side of the first filter opening with a smaller extension dimension, the first direction intersecting the second direction.

2. The filter opening arrangement structure according to claim 1, wherein the first filter opening is a blue filter opening, a red filter opening, or a green filter opening.

3. The filter opening arrangement structure according to claim 1, wherein the filter openings further comprise a second filter opening having an extension dimension in the first direction smaller than an extension dimension in the second direction of the second filter opening, and the light-transmitting hole is located between the first filter opening and the second filter opening.

4. The filter opening arrangement structure according to claim 3, wherein the first filter opening is one of a blue filter opening and a red filter opening, and the second filter opening is the other of the blue filter opening and the red filter opening; and
the first filter opening has an elliptical shape, the second filter opening has an elliptical shape.

5. The filter opening arrangement structure according to claim 3, wherein each light-transmitting hole is located between a respective first filter opening and an adjacent second filter opening.

6. The filter opening arrangement structure according to claim 3, wherein a width of the first filter opening in the first direction is equal to a width of the second filter opening in the first direction.

7. The filter opening arrangement structure according to claim 6, wherein the first filter opening comprises two first straight edges disposed opposite to each other in the first direction and two first arc-shaped edges disposed opposite to each other in the second direction, the two first arc-shaped edges being configured to protrude in directions away from each other, and the two first straight edges and the two first arc-shaped edges defining the first filter opening; and
the second filter opening comprises two second straight edges disposed opposite to each other in the first direction and two second arc-shaped edges disposed opposite to each other in the second direction, the two second arc-shaped edges being configured to protrude in directions away from each other, and the two second straight edges and the two second arc-shaped edges defining the second filter opening.

8. The filter opening arrangement structure according to claim 6, wherein an edge of the light-transmitting hole that faces the second filter opening is parallel to the two second straight edge, and an edge of the light-transmitting hole that faces the first filter opening is parallel to the two first straight edge.

9. The filter opening arrangement structure according to claim 3, wherein the first filter opening is located at a first vertex of a first virtual polygon, and the second filter opening is located at a second vertex of the first virtual polygon, the first vertex and the second vertex being disposed alternately and spaced apart from each other, and the first virtual polygon being a trapezoid; and
the filter openings further comprise a third filter opening located within the first virtual polygon.

10. The filter opening arrangement structure according to claim 9, wherein the third filter opening has an extension dimension in the first direction greater than or equal to an extension dimension in the second direction.

11. The filter opening arrangement structure according to claim 1, wherein a minimum spacing between the filter opening and the light-transmitting hole is in a range from 5 μm to 8 μm;
the filter openings comprise a first filter opening and a second filter opening, the first filter opening and the second filter opening being disposed on two sides of the same light-transmitting hole, and a minimum spacing between the first filter opening and the light-transmitting hole being in a range from 5 μm to 8 μm;
or a minimum spacing between the second filter opening and the light-transmitting hole being in a range from 5 μm to 8 μm.

12. A display panel, comprising:
a substrate; and
a filter layer disposed on one side of the substrate, wherein a light filter layer comprises a plurality of filter openings and a plurality of light-transmitting holes, the filter openings and the light-transmitting holes are arranged according to a filter opening arrangement structure of claim 1.

13. The display panel according to claim 12, wherein the filter openings further comprise a second filter opening having an extension dimension in the first direction smaller than an extension dimension in the second direction, wherein a plurality of first filter openings and a plurality of second filter openings are distributed in an array, and an orthographic projection of the light-transmitting hole on a substrate is located between an orthographic projection of the first filter opening on the substrate and an orthographic projection of the second filter opening on the substrate.

14. The display panel according to claim 13, wherein the display panel further comprises a driving device layer comprising a plurality of first power supply signal lines, an orthographic projection of the first power supply signal line on the substrate being configured to extend in the second direction, wherein orthographic projections of the first power supply signal lines on the substrate are disposed side by side in the first direction,
wherein the orthographic projection of at least one of the first filter openings on the substrate at least partially overlaps with the orthographic projection of one of the first power supply signal lines on the substrate, and the orthographic projection of the first filter opening on the substrate is disposed symmetrically with respect to the orthographic projection of the first power supply signal line on the substrate, or the orthographic projection of at least one of the second filter openings on the substrate at least partially overlaps with the orthographic projection of one of the first power supply signal lines on the substrate, and the orthographic projection of the second filter opening on the substrate is disposed symmetrically with respect to the orthographic projection of the first power supply signal line on the substrate.

15. The display panel according to claim 12, further comprising a pixel defining layer located between the substrate and the filter layer, wherein the pixel defining layer is provided with a plurality of pixel openings disposed corresponding to the filter openings, and an orthographic projection of the pixel opening on a substrate at least partially overlaps with an orthographic projection of the filter opening on the substrate;
the orthographic projection of the pixel opening on the substrate is within the orthographic projection of the filter opening on the substrate; and
the orthographic projection of the filter opening on the substrate is defined as a projection I, and the orthographic projection of the pixel opening on the substrate is defined as a projection II, an edge of the projection I being disposed equidistantly from an edge of the projection II.

16. The display panel according to claim 12, further comprising a driving device layer disposed between the substrate and the filter layer, the driving device layer comprising a plurality of driving units, wherein an orthographic projection of the light-transmitting hole on the substrate is defined as a first orthographic projection which is located between orthographic projections of two of the driving units on the substrate.

17. The display panel according to claim 16, wherein the driving unit comprises a driving transistor, and the first orthographic projection is located between orthographic projections of the two driving transistors of two adjacent driving units on the substrate.

18. The display panel according to claim 17, wherein the orthographic projections of the two driving transistors on the substrate are respectively located on opposite sides of the first orthographic projection in the first direction; and
the driving transistors located on two sides of the first orthographic projection in the first direction are symmetrically distributed.

19. The display panel according to claim 18, the driving transistor comprises a semiconductor layer, the semiconductor layer comprising a source region, a drain region, and a channel region located between the source region and the drain region, wherein the channel region is configured to protrude with respect to the source region and the drain region in the second direction;
the driving device layer further comprises a second signal line extending in the first direction and electrically connected to the driving units, and an orthographic projection of the channel region on the substrate is configured to protrude in a direction away from an orthographic projection of the second signal line on the substrate;
an orthographic projection of the drain region on the substrate is located between an orthographic projection of the source region on the substrate and the first orthographic projection; and
the orthographic projections of the two driving transistors on the substrate are respectively located on opposite sides of the first orthographic projection in the first direction, and a distance between the orthographic projection of the source region of at least one of the driving transistors on the substrate and the orthographic projection of the second signal line on the substrate in the second direction is greater than a distance between the orthographic projection of the drain region on the substrate and the orthographic projection of the second signal line on the substrate in the second direction.

20. The display panel according to claim 12, further comprising a driving device layer, the driving device layer comprising a first signal line and a second signal line, wherein an orthographic projection of the first signal line on the substrate and an orthographic projection of the second signal line on the substrate both extend in a first direction, the orthographic projection of the first signal line on the substrate and the orthographic projection of the second signal line on the substrate are disposed side by side in a second direction which intersects the first direction, and an orthographic projection of the light-transmitting hole on the substrate is defined as a first orthographic projection which is located between the orthographic projection of the first signal line on the substrate and the orthographic projection of the second signal line on the substrate.
